(19) United States
(12) Patent Application Publication
(10) Pub. No.: US 2024/0242873 A1
(43) Pub. Date: Jul. 18, 2024

(54) ELECTROMAGNETIC COMPONENTS WITH PLANAR AND NON-PLANAR CONDUCTORS

(71) Applicant: Resonant Link, Inc., South Burlington, VT (US)

(72) Inventors: Phyo Aung Kyaw, Winooski, VT (US); Aaron Stein, Essex, VT (US); Charles R. Sullivan, West Lebanon, NH (US)

(73) Assignee: Resonant Link, Inc., South Burlington, VT (US)

(21) Appl. No.: 18/418,979

(22) Filed: Jan. 22, 2024

Related U.S. Application Data
(63) Continuation of application No. PCT/US2022/038179, filed on Jul. 25, 2022.
(60) Provisional application No. 63/226,022, filed on Jul. 27, 2021.

(51) Int. Cl. H01F 27/28; G06F 30/39; H01F 27/24; H01F 27/29

(52) U.S. Cl. CPC H01F 27/2804; G06F 30/39; H01F 27/24; H01F 27/29

(57) ABSTRACT

An example of an electromagnetic component includes a thin conductor layer having traces extending along a circumferential direction of the electromagnetic component and having widths extending along a radial direction of the electromagnetic component. The widths can be selected such that alternating current distributions in the traces approximate an alternating current distribution in a single trace having a same radial extent as the traces.

### RELATED APPLICATIONS

This application is a Continuation of International Patent Application Serial No. PCT/US2022/038179, filed Jul. 25, 2022, which claims the benefit under 35 U.S.C. § 119(e) of U.S. Provisional Application Ser. No. 63/226,022, filed Jul. 27, 2021, which is incorporated herein by reference in its entirety.

### BACKGROUND

### 1. Technical Field

The apparatus and techniques described herein relate to electromagnetic components.

### 2. Discussion of the Related Art

Electromagnetic components, such as inductors and transformers, may include one or more windings formed of electrical conductors. Some electromagnetic components have one or more magnetic cores.

### SUMMARY

Some aspects relate to an electromagnetic component, comprising: a thin conductor layer having traces extending along a circumferential direction of the electromagnetic component and having widths extending along a radial direction of the electromagnetic component, wherein the widths are selected such that alternating current distributions in the traces approximate an alternating current distribution in a single trace having a same radial extent as the traces.

The traces may include a first trace having a first width and a second trace having a second width. The first trace may be an innermost trace of the thin conductor layer and the second width is greater than the first width.

The traces may include a third trace having a third width greater than the second width, the third trace being farther from a center of the electromagnetic component in a radial direction than the second trace.

The electromagnetic component may further comprise a magnetic core.

The thin conductor layer may be disposed within the magnetic core.

The magnetic core may comprise a center post and an outer rim and the thin conductor layer may be between the center post and the outer rim.

The traces may be in series with one another.

Some aspects relate to an electromagnetic component, comprising: a thin conductor layer having traces extending along a circumferential direction of the electromagnetic component and having widths extending along a radial direction of the electromagnetic component, wherein the traces include a first trace having a first width, wherein the first trace is an innermost trace of the thin conductor layer, wherein the first width is selected such that

$${w}_{1} < 0.97 * \frac{{r}_{w o u t} - {r}_{w i n}}{{N}^{5 / 4}} ,$$

and wherein w₁ is the first width, r_{win} is an inner radius of the traces, r_{wout} is an outer radius of the traces, and N is a quantity of the traces.

The traces may further include a second trace having a second width larger than the first width, the second trace being radially adjacent the first trace, wherein the second width is selected such that w₂\sqrt{2}*w₁, wherein w₂ is the width of the second trace.

The traces may further include a third trace having a third width larger than the first width, the third trace being radially adjacent the second trace on an outer side of the second trace, wherein the third width is selected such that w₃>\sqrt{3}*w₁, wherein w₃ is the width of the third trace.

Some aspects relate to an electromagnetic component, comprising: a thin conductor layer having N traces extending along a circumferential direction of the electromagnetic component and having widths extending along a radial direction of the electromagnetic component, wherein the traces include a first trace having a first width w₁, wherein the first trace is an innermost trace of the first layer, and the traces include second and third traces having widths wₖ>\sqrt{k}*w₁, wherein k is an index of the second and third traces equal to 2 or 3, respectively, with the second trace being radially adjacent to the first trace and the third trace being radially adjacent to the second trace on an outer side of the second trace.

The traces may further comprise at least one additional trace outside the third trace having a width wₖ>2*w₁, wherein wₖ is a width of the trace having index k, wherein the index k of a trace is the number of the trace starting with the innermost trace as index 1 and incrementing by one counting radially outward from the innermost trace.

In some aspects,

$${w}_{1} < 0.97 * \frac{{r}_{w o u t} - {r}_{w i n}}{{N}^{5 / 4}} ,$$

wherein r_{win} is an inner radius of the traces and r_{wout} is an outer radius of the traces.

Some aspects relate to a method of designing an electromagnetic component comprising a thin conductor layer having traces extending along a circumferential direction of the electromagnetic component and having widths extending along a radial direction of the electromagnetic component, the method comprising: obtaining a distribution of alternating current density vs. radial position of the electromagnetic component for a single trace having a same radial extent as the traces; integrating or summing the distribution over radial position to determine a total alternating current; dividing the total alternating current by a number N of the traces to determine the alternating current per trace; and selecting the widths of each of the N traces, which, based on the distribution, results in the N traces having the determined alternating current per trace.

The determining of the widths may comprise selecting a width of a first trace by integrating or summing along the distribution along a radial direction until a width is reached in which the alternating current for the first trace is equal to the determined alternating current per trace.

The first trace may be an innermost or outermost trace of the first layer.

Some aspects relate to an electromagnetic component, comprising: a winding, including: first and second terminals; and a conductor comprising a plurality of turns connected in series between the first and second terminals; and a series turn capacitance corresponding to a first turn of the plurality of turns.

The series turn capacitance may be in series with the first turn and connected to the first turn at a location different from the first and second terminals.

The series turn capacitance may be connected in series between first and second portions of the first turn.

The plurality of turns may further comprise a second turn, the series turn capacitance is a first series turn capacitance, and the electromagnetic component may further comprise a second series turn capacitance corresponding to the second turn.

The series turn capacitance may include a standalone capacitor or an integrated capacitance.

The series turn capacitance may include a standalone capacitor that is a discrete capacitor.

The winding may be formed in a plurality of layers and the electromagnetic component may comprise vias between capacitor pads for the standalone capacitor, the vias connecting an inner layer of the plurality of layers to another capacitance.

The series turn capacitance may include an integrated capacitance formed by an overlap between first and second layers of conductors separated by a dielectric.

The electromagnetic component may comprise a plurality of series turn capacitances formed by respective overlaps between the first and second layers of conductors.

The first and second layers of conductors may be conductor layers of a printed circuit board.

The first and second layers of conductors may be electrode layers in a multilayer ceramic capacitor (MLCC) or low-temperature co-fired ceramic (LTCC) processes.

Alternating current may flow through the winding between the first and second layers through the series turn capacitance and in a circumferential direction of the winding,

A capacitance value of the series turn capacitance may be selected to provide an impedance of between 50% and 200% of an inductive impedance of the first turn.

A capacitance value of the series turn capacitance may be selected such than an impedance of the series turn capacitance cancels an impedance of the first turn.

The series turn capacitance may comprise a plurality of series turn capacitances for the first turn.

Some aspects relate to an electromagnetic component, comprising: a winding including a thin conductor layer having a trace with at least first and second turns extending in a circumferential direction, the first turn having a first portion with a constant radius, the second turn having a second portion with a constant radius, the trace further including a third portion that is a transition portion extending between the first and second portions.

The trace may further have a third turn extending in the circumferential direction, the third turn having a fourth portion with a constant radius, the trace further including a fifth portion that is a second transition portion extending between the fourth and fourth portions.

The third and fifth portions may be within a transition region.

The transition region may have an area that is less than one quarter of an area of the winding.

A first terminal of the winding may extend below or above the transition region.

First and second terminals of the winding may extend through a backplate of a magnetic core.

First and second terminals of the winding may be stacked such that their sides with widest dimensions face one another.

The foregoing summary is provided by way of example and is not intended to be limiting.

### BRIEF DESCRIPTION OF DRAWINGS

In the drawings, each identical or nearly identical component that is illustrated in various figures is represented by a like reference character. For purposes of clarity, not every component may be labeled in every drawing. The drawings are not necessarily drawn to scale, with emphasis instead being placed on illustrating various aspects of the techniques and devices described herein.

FIGS. 1A and 1B show examples of electromagnetic components with thin-layer conductors having one turn and three turns, respectively.

FIG. 2 shows a plot of the quality factor of example planar electromagnetic components, such as those shown in FIG. 1A and FIG. 1B, having windings with different number of turns in a single layer in a fixed winding region.

FIG. 3 shows an electromagnetic component having thin-layer conductors of varying width.

FIG. 4 shows a plot of current density vs radial position for three different designs.

FIGS. 5A and 5B show examples of windings including series turn capacitances formed by standalone capacitors.

FIGS. 6A-6D illustrate via placement between capacitor pads.

FIG. 7 shows a cross-sectional view of a structure including integrated series turn capacitances between two layers of thin-layer conductors.

FIGS. 8A-8D show various views of a winding including integrated series turn capacitances.

FIG. 9 shows a winding with a transition region between turns.

FIGS. 10A and 10B show simulation results illustrating current crowding at edges of a transition region.

FIGS. 11A and 11B show the magnetic field due to the radial component of the traces in the transition region can be compensated by positioning the return trace above or below the transition region. FIG. 12B shows a simulation result illustrating the compensation.

FIGS. 13A and 13B illustrate performance can be improved by stacking the two planar conductors.

FIG. 14 illustrates a stacked lead design.

FIG. 15 illustrates the winding leads may extend through an opening in the backplate of the magnetic core.

### DETAILED DESCRIPTION

The inventors have developed several improvements to electromagnetic components.

Some electromagnetic components include thin-layer conductors (also referred to herein as thin conductor layers). Thin-layer conductors may have the advantages of having a low profile and a low cost of manufacturing compared to alternatives such as magnet-wire or litz-wire windings, for example. Thin-layer conductors may be formed in a variety of processes, and in one example may be formed from printed circuit board (PCB traces).

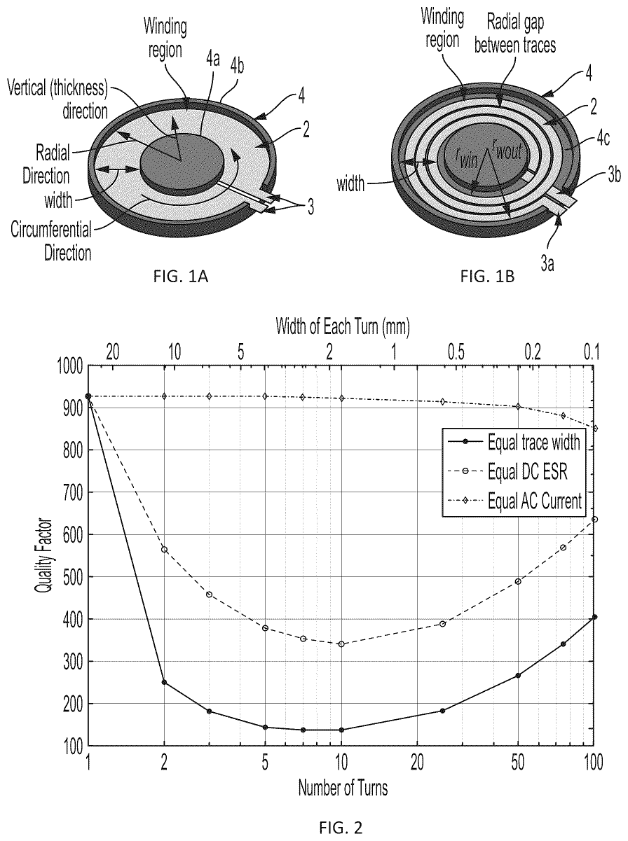

FIG. 1A shows an example of an electromagnetic component with a winding (also termed a coil) that includes a thin-layer conductor 2 having a single turn. Also illustrated in FIG. 1A are leads 3 of the winding, and a magnetic core 4. The magnetic core 4 in this example is pot core having a center post 4a and an outer rim 4b. Optionally, the magnetic core 4 may have a backplate (not shown in FIG. 1A). Also illustrated in FIG. 1A are directions relative to the electromagnetic component such as are used in a polar coordinate system, including a radial direction extending radially from the center of an imaginary circle approximating the outline of the electromagnetic component from a top view, a circumferential direction perpendicular to the radial direction at respective circumferential positions around the electromagnetic component, and a vertical (thickness) direction extending perpendicularly to the radial and circumferential directions.

FIG. 1B shows an example of an electromagnetic component with a winding that includes a thin-layer conductor 2 having a plurality of turns, specifically three turns, in this example. Each turn corresponds to one revolution of the winding about a center of the winding. The winding of FIG. 1B spirals gradually from lead 3a towards the center before returning underneath the turns of the winding as a return lead 3b. Also visible in FIG. 1B is a backplate 4c of the magnetic core 4. The turns of the winding and the return lead 3b are electrically insulated from one another by a dielectric material (not shown).

Electromagnetic components with thin-layer conductors may comprise a single conductor layer (as shown in FIGS. 1A and 1B) or a plurality of layers. Examples of electromagnetic components having a plurality of layers of thin-layer conductors are discussed further below.

Thin-layer windings are windings of one or more thin-layer conductors. Thin layer conductors are electrical conductors in which the thickness of the winding is much smaller than its width (e.g., at least 10 times smaller). For example, the thin-layer winding shown in FIG. 1A may be formed of a conductive foil having a thickness (in the vertical direction) much smaller than its width (in the radial direction). For a thin-layer winding with a plurality of turns, the thin-layer winding has a thickness that is much smaller (e.g., at least 10 times smaller) than the width (radial extent) of all the turns in the thin-layer winding. For example, in FIG. 1B, the width of the thin-layer winding is the radial extent of the winding across all three traces, which in this case are three turns connected in series. Some examples of thin-layer conductors or their applications may include, but are not limited to, foil layers forming a flat current loop (e.g. C-shaped, arc-shaped, rectangular-shaped, or any polygon-shaped conductors); edge-wound conductors; printed circuit boards; multilayer self-resonant structures (U.S. Pat. Nos. 10,109,413 and 10,707,011, PCT/US2017/043377, patent application Ser. No. 16/994,448); inductively coupled current loops (patent application PCT/US2021/15260); multilayer conductors with integrated capacitance (patent application PCT/US2021/041387); and low-frequency resonant structure (provisional application PCT/US2021/041387), and any of the foil conductors mentioned before in which the conductor is patterned.

The thin-layer conductors (also referred to herein as electrical conductors or simply conductors) may be made of any electrically conductive material or combination of materials, including but not limited to one or more metals such as silver, copper, aluminum, gold and titanium, and non-metallic materials such as graphite. The electrically conductive material may have an electrical conductivity of higher than 1 MS/m, optionally higher than 200 kS/m. The thin-layer conductors may have any physical shape including, but not limited to, solid material, foil, conductors laminated on a substrate, printed circuit board traces, electrode layers in multilayer ceramic capacitor (MLCC) processes, electrode layers in low-temperature co-fired ceramic (LTCC) processes, integrated circuit traces, or any combination of thereof.

Layers of thin-layer conductors, or the different traces (e.g., turns) of thin-layer conductors, may be separated by any electrically non-conductive material (dielectric material) or combination of materials, including but not limited to one or more of air, FR4, PLA, ABS, polyimide, PTFE, polypropylene, Rogers Substrates, plastic, glass, alumina, ceramic, dielectric or ceramic layers in multilayer ceramic capacitor (MLCC) processes, or dielectric or ceramic layers in low-temperature co-fired ceramic (LTCC) processes.

As illustrated in FIG. 1A and FIG. 1B, the thin-layer conductor(s) may be positioned within a winding region between a center post and an outer rim of the magnetic core. However, the techniques and apparatus described herein are not limited to particular types of magnetic cores, as in some magnetic cores there may not be a center post and/or outer rim, and in some cases a magnetic core may be omitted.

If a magnetic core is present, the magnetic core may be, wholly or partially, made of one or more ferromagnetic materials, which have a relative permeability of greater than 1, optionally greater than 10. The magnetic core materials may include, but are not limited to, one or more of iron, various steel alloys, cobalt, ferrites including manganese-zinc (MnZn) and/or nickel-zinc (NiZn) ferrites, nanogranular materials such as Co—Zr—O, and powdered core materials made of powders of ferromagnetic materials mixed with organic or inorganic binders. However, the techniques and devices described herein are not limited as to the particular material of the magnetic core. The shape of the magnetic core may be: a pot core, a sheet (I core), a sheet with a center post, a sheet with an outer rim, RM core, P core, PH core, PM core, PQ core, E core, EP core, or EQ core, by way of example. However, the techniques and devices described herein are not limited to the particular magnetic core shape. An electromagnetic component may comprise one or a plurality of magnetic cores, with or without an air gap in the magnetic flux path; in some embodiments, for example with open-faced pot cores, widely used for wireless power transfer, the air gap in the magnetic flux path may be substantial.

### Variable Trace Width Based on AC Current Distribution

Electromagnetic components with thin-layer conductors can have a high performance (i.e., a low loss or a high quality factor) if the winding is made up of a single-turn thin-layer conductor—a thin-layer conductor wrapped one time around a center mandrel (for example the center post in the magnetic core in FIG. 1A)—or if the winding is made up of a plurality of turns, each with a width in the radial direction smaller than the skin depth of the conductor at the frequency of operation.

FIG. 2 shows the quality factor of example planar electromagnetic components, such as those shown in FIG. 1A and FIG. 1B, having windings with different number of turns in a single layer in a fixed winding region.

In FIG. 2 the curve labeled ‘Equal Trace Width’ shows the quality factor of the example electromagnetic components in FIG. 1A and FIG. 1B as a function of the number of turns (or the width of each turn), with the width of each turn (i.e., in the radial direction of FIG. 1B) being the same. Quality factor signifies the performance of an electromagnetic component; the higher the quality factor, the higher the performance and the lower the loss in the electromagnetic component. It can be seen that a single-turn winding (as in the example of FIG. 1A) has a quality factor Q above 900, but adding a second turn, or trace, to the winding reduces the quality factor to around 250 (73.4% decrease in Q). The performance, or the quality factor, is the lowest for around 7-10 turns (85% decrease in Q), and increases as the number of turns increases above 10. The quality factor vs. number of turns plotted in FIG. 2 is based on an example planar electromagnetic component design; the particular values of the quality factor and the number of turns depends on the design of the electromagnetic component, but the trend of the quality factor as a function of the number of turns described herein remains similar for different designs. The remaining curves of FIG. 2 are discussed below.

Many applications of electromagnetic components (for example, inductors, transformers, wireless charging coils) may specify that the number of turns be neither too few (for example fewer than 5) nor too many (for example more than 20). This specification for a particular number of turns in some applications may coincide with the number of turns for which the quality factor for an electromagnetic component with thin-layer conductors is minimum (for example 7 turns in FIG. 2), or another number of turns resulting in low Q, and may result in thin-layer conductors being unsuitable or less effective than desired.

The inventors have developed techniques for designing electromagnetic components with thin-layer conductors which have a good quality factor independent of the number of turns. Such techniques involve varying the radial width of each trace. That is, different traces in the same layer or plane may have different radial widths. The radial width of a trace may be a function of its radial distance from the center point. In particular, the radial width of each trace may be selected to approximate an alternating current distribution in a single trace having a same radial extent as the traces in the winding. The apparatus and techniques described herein are applicable for a winding having any number of two or more traces or turns.

An electromagnetic component having trace widths selected according to such a technique may achieve a high quality factor. For example, as shown in FIG. 2, such a technique can result in a quality factor of around 900 independent of the number of turns (‘Equal AC current’). The technique can be useful in different applications by introducing a degree of freedom in the design of electromagnetic components with thin-layer conductors.

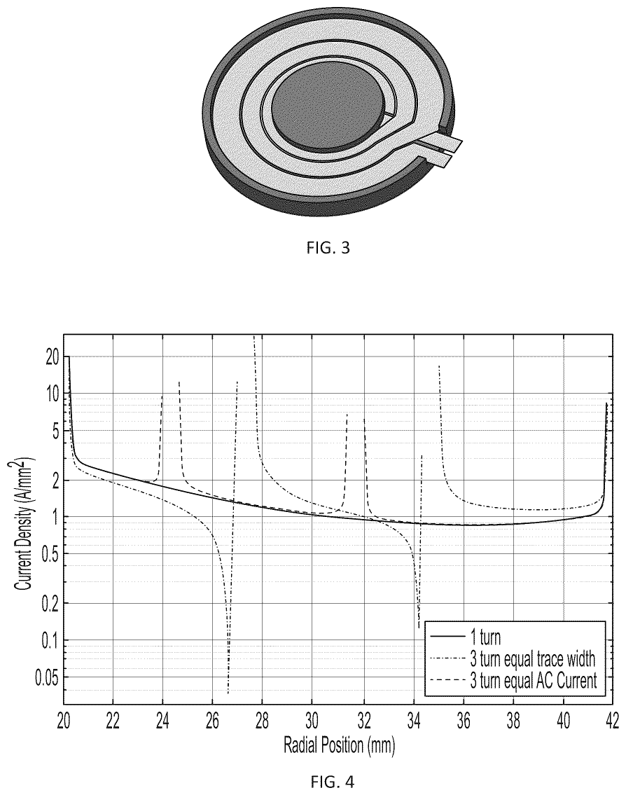

In some embodiments, the performance of planar electromagnetic components can be improved, or their winding loss can be reduced, by as much as, or more than, an order of magnitude if the radial width of each turn is chosen using the techniques described herein (e.g., optimally). One example of such an electromagnetic component with three traces in one layer is shown in FIG. 3. FIG. 3 illustrates that the inner trace(s) may be formed with smaller widths than the outer trace(s) to approximate a radial alternating current distribution in a single trace having a same radial extent as the traces in the winding. The reason for the inner trace(s) having smaller width(s) can be appreciated from FIG. 4, which shows current in a single-turn winding tends to crowd near the inner edge.

Conventionally, the radial widths of each turn in a multi-turn planar coil may be selected by equalizing the direct current (DC) resistance of each turn; the radially outer turns, which have longer average turn lengths, are typically selected to have proportionally larger widths. Even though this strategy (‘Equal DC ESR’ in FIG. 2) may provide better performance than a design where the radial widths of all traces are equal (‘Equal trace width’ in FIG. 2), the resulting performance of such a multi-turn winding may be as low as 37% of that of a single-turn winding (63% decrease in Q).

As mentioned above, the inventors have developed a technique for selecting the radial widths of each turn in a multi-turn planar coil such that the resulting coil has a good quality factor independent of the number of turns. As shown in FIG. 2, planar coils with a single-turn winding provide significantly higher quality factor compared to those with a multi-turn winding. A single-turn winding does not have a break in the radial direction in the conductive material of the winding of the planar coil, and the radial AC current distribution in the winding is naturally adjusted so that the magnetic field lines produced are mostly parallel to the planar winding, thereby reducing the loss in the winding. In contrast, a multi-turn winding—whether the width of each turn is selected to be equal, or to provide equal DC equivalent series resistance (ESR)—has breaks in the radial direction in the conductive material of the winding, which disrupts the natural adjustment of current distribution and results in current crowding to the edge of each turn, hence leading to significant winding losses. This current-crowding problem is also made severe because the current in each turn—with equal widths or equal direct current (DC) ESR—results in an alternating current (AC) current distribution which provides magnetic field lines that are not parallel to the winding. As mentioned above, an effective strategy for achieving a high-quality-factor multi-turn planar coil is to select the width of each turn such that the relative AC current distribution in the multi-turn coil mimics that of a single-turn coil. In other words, the width of each turn in a multi-turn winding with N turns (N-turn winding) can be chosen by simulating or calculating the AC current distribution of a single-turn winding with similar inner and outer radii, and dividing the single-turn winding into N sub-rings with different widths in which the total AC current of each sub-ring based on the simulated or calculated single-turn AC current distribution is equal.

The following steps may be used to select the trace widths with equal alternating currents in each turn for a N-turn winding with an inner radius r_{win} and an outer radius r_{wout}, where Twin is the inner radius of the innermost turn and r_{wout} is the outer radius of the outermost turn. In this example, the winding is located in an annular region (winding region) defined by the area between a circle of radius r_{win} in and circle of radius r_{wout}.
1) The relationship between current density and radial position for a single trace having an inner radius r_{win} and an outer radius r_{wout} may be obtained. In some embodiments, such a relationship (e.g., a curve) may be obtained by simulation or calculation. One example of such a simulated relationship is shown by the solid line in FIG. 4 for an inner radius of 20.25 mm and an outer radius of 41.75 mm.
2) The number of desired turns/traces N is selected. Step 2 may be performed during the design process for an electromagnetic component, and may be performed before or after step 1. The number of turns/traces N is typically dictated by the particular application, and may be a given parameter for the design of the electromagnetic component. N is typically selected in the design of the larger system in which the electromagnetic component is used. For example, a particular inductance would be needed in a power converter for a desired current ripple; and to achieve that inductance, a specific number of turns N would be selected. The traces may be designed to be connected in any configuration, such as in series or parallel.
3) The total AC current in the current density relationship vs position from step 1 may be determined by integrating or summing the relationship determined in step 1 over radial position across the radial extent of the electromagnetic component. This step may be performed before or after step 2.
4) The total AC current determined in step 3 is divided by the number of desired traces N. This gives the AC current per trace according to the current distribution in step 1.
5) The width of each trace may be determined such that the AC current for each trace, as integrated or summed over the relationship from step 1 over the width, is equal to the AC current per trace determined in step 4. For example, the width of a first trace (e.g., starting with the innermost or outermost trace) may first be calculated. The width may be calculated by integrating or summing along the relationship or curve determined in step 1 until the AC current for the trace is equal to the AC current determined in step 4. The widths of the remaining traces may be calculated similarly. The widths may be calculated in various orders, such as from the inner to the outer radius, from the outer to the inner radius.

The AC current distribution, as a function of the radial position in the winding with an inner radius of 20.25 mm and outer radius of 41.75 mm, for 1) a single-turn coil, 2) a multi-turn coil with equal trace width for each turn, and 3) a multi-turn coil that mimics the AC current distribution of a single-turn coil are compared in FIG. 4. The single-turn coil has a continuous AC current distribution, with higher current density at the inner and outer edge of the winding. A multi-turn coil with equal trace width for each turn results in an AC current distribution that is significantly different from that of a single-turn winding; the current density is significantly higher in the inner edge of each turn than the outer edge, which results in a significantly high winding loss. The described technique, which equates the total AC current in each turn based on the AC current distribution of a single-turn winding, results in a multi-turn coil with an AC current distribution that approximately follows that of a single-turn winding, with slightly higher current density at the edges of each turn. Even though the slightly higher current density at the edges of each turn results in higher loss compared to a single-turn coil, the increase in loss is minimal and results in a quality factor that approximately equals that of a single-turn winding.

The effectiveness of the techniques described herein can be seen in FIG. 2, where the quality factor of a multi-turn coil that equates the AC current (‘Equal AC current’) remains approximately constant for 1 to 50 turns and decreases only slightly for up to 100 turns, whereas the quality factor of a multi-turn coil that equates the width or the DC ESR is significantly lower than that of a similar single-turn coil.

The radial gap between adjacent turns may depend on the fabrication process. In some embodiments, the radial gap may be made as small as possible. This is in contrast to the literature, which states that spacing should be at last the width of each turn/trace, which reduces performance as the copper area would be reduced by a factor of at least two. Using a radial gap that is as small as possible between traces allows for a larger area of copper, which makes use of the winding region more effectively. This gap will reduce the width of each turn since it cannot be infinitesimal. Accordingly, in some embodiments the radial gap between adjacent turns/traces is less than the with of a turn/trace and greater than zero. The exact position of this gap with respect to the infinitesimal cut is less important, as long as the gap surrounds the infinitesimal cut.

### Characterization of Final Coil Design

The following description applies to coils with N different turns/traces in a single layer. These N different traces may be connected in parallel or series or some combination of series and parallel, and the traces in different layers may be connected in parallel or series or some combination of series and parallel. N traces connected in series will result in N-turn coil.

For each layer with N traces, the traces are labeled as k=1 to N, where k=1 represents the innermost turn and k=N represents the outermost turn. The inner radius of the planar coil is denoted by r_{win} and the outer radius is denoted by r_{wout}.

The planar coils designed according to the method mentioned above can be characterized as follows. For coils with N traces in a layer, Table 1 describes the trace widths of the kth trace wₖ (where k=1 to N−1) for a winding design according to the techniques described herein. The width of the outermost trace w_{N} is determined by the total available width and the widths of the other N−1 turns.

TABLE 1

| Trace | |
|---|---|
| number | |
| (k) | Description for trace width |
| k = 1 | ${w}_{k} < 0.97 * \frac{{r}_{wout} - {r}_{w i n}}{{N}^{5 / 4}}$ |
| k = 2 | wₖ > \sqrt{k} * w₁ (at least \sqrt{k} times the width of the innermost turn) |
| k = 3 | |
| k >= 4 | Wₖ > 2 * w₁ (at least 2 times the width of the innermost turn) |

Adding a Capacitance into the Winding

Conventional coils are constructed from one or more turns of an electrically conductive material wrapped into an inductive current loop with two ends (terminals). Coils may be optionally placed in a magnetic core. In a conventional coil, one or more capacitors may be connected to the two terminals of the winding. The one or more capacitors connected to the two terminals of the winding may provide a resonant capacitance.

In some embodiments, the resonant capacitance may be distributed into a plurality of capacitances connected in series with respective turns of the coil. A capacitance connected in series with a turn of a coil is also termed herein a series turn capacitance. The capacitance value of the series turn capacitance may be selected to cancel or approximately cancel the inductive impedance of the turn with which the capacitor is connected in series. However, the techniques and apparatus described herein are not limited to exact cancellation. Partial or extra cancellation can be useful (e.g., capacitive reactance is 50% to 200% the inductive reactance of the turn). In wireless power transfer, or other resonant power conversion applications, the series turn capacitance value can be chosen to resonate with the inductance of the turn, which provides the resonance used for wireless power transfer or power conversion.

Distributing some or all of the resonant capacitance into a plurality of capacitances in series with the turns of a series resonant coil may reduce loss in the circuits, winding, and leads. Distribution of the resonant capacitance into one or more turns as a series turn capacitance reduces the voltage (electrical potential difference) between each turn, or between the turns and the return current path, and therefore reduces or eliminates the excitation of parasitic capacitances. In some embodiments, capacitive devices having a lower voltage rating may be used for a capacitance in series with each turn as opposed to providing a single resonant capacitance for the entire coil. Series turn capacitances may enable higher power operation by distributing heat generation more uniformly within the coil.

Experimental results show an increase in Q using series turn capacitances. A 18 cm 4-turn coil with a capacitor connected at the lead (conventional design) results in a measured quality factor of 150; adding a series turn capacitor in each turn increases that quality factor to 850.

In some embodiments, a series turn capacitance may be included for each and every turn of the coil, which may provide high performance. However, the apparatus and techniques described herein are not limited in this respect, as a series turn capacitance may be provided corresponding to any one or more turns of the coil.

The inclusion of one or more series turn capacitances may be applied to a resonant coil constructed with any type of conductors, including, but not limited to: litz wire, PCB traces, foil, magnet wire, conductors laminated on substrate layers, inductively coupled current loops, multilayer self-resonant structures, electrode layers in multilayer ceramic capacitor (MLCC) processes, electrode layers in low-temperature co-fired ceramic (LTCC) processes, integrated circuit traces and others. The conductors may be planar or non-planar. Examples of non-planar coils include solenoids and barrel-wound coils. The coil or winding may be placed in a magnetic core, but placing them in a magnetic core is optional.

A series turn capacitance may be provided by a variety of capacitive devices, such as standalone capacitors or integrated capacitors, for example. Standalone capacitors may be formed by any of a variety of devices. Standalone capacitors are devices with dominant capacitive (negative reactive) impedance at the desired frequency of operation; they may have inductive (positive reactive) impedance less than the capacitive impedance at the frequency of operation, and optionally less than 20% of the capacitive impedance at the frequency of operation. In some embodiments, the one or more standalone capacitors are discrete capacitors. The standalone capacitor(s) may have individual packaging which can be galvanically connected to electrical conductors (e.g., by soldering). The standalone capacitor(s) may include, but are not limited to one or more of ceramic capacitors, multilayer ceramic capacitors (MLCCs), film capacitors, mica capacitors, PTFE capacitors, tantalum capacitors, tantalum-polymer capacitors, thin film capacitors, electric double layer capacitors, polymer capacitors, electrolytic capacitors, niobium oxide capacitors, silicon capacitors, variable capacitors, and any combination, network or array of devices.

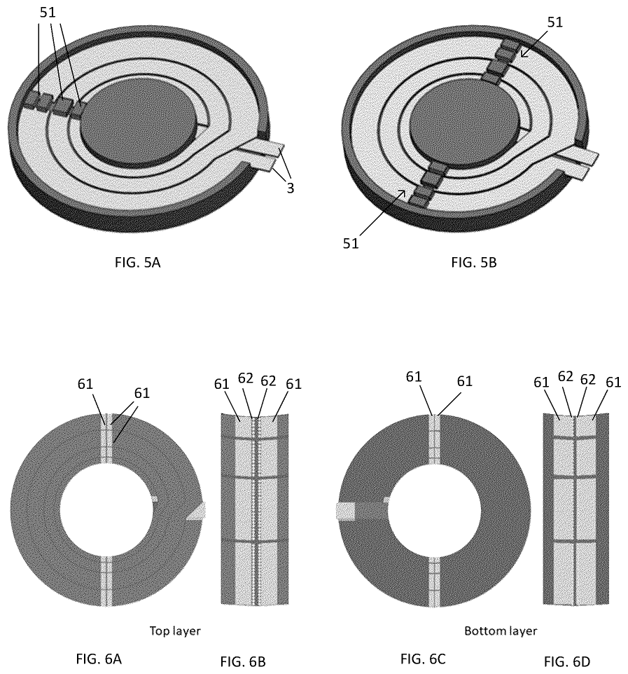

Examples of coils including series turn capacitances formed by standalone capacitors are shown in FIGS. 5A and 5B. FIG. 5A shows a three-turn winding formed of thin conductor layers, in which each turn includes a series turn capacitance 51 formed by one or more standalone capacitors. In this example, a single series turn capacitance 51 is located 50% of the way through each turn, 180 degrees away from the two terminals 3. However, the series turn capacitance 51 need not be located at this position, and need not be limited to a single series turn capacitance for a turn.

In some embodiments, providing more than one series turn capacitance for a turn may improve thermal distribution. When more than one series turn capacitance is included for a turn, the one or more series capacitances may be separated by a portion of the conductor. FIG. 5B shows an example in which each turn includes two series turn capacitances 51 located 180 degrees apart from one another. However, the number of series turn capacitances for a turn is not limed to two, as any number of series turn capacitances may be included. The series turn capacitances need not be 180 degrees apart from one another, and can be anywhere in a turn.

### Standalone Capacitor Connection and Placement

In a multilayer structure a challenge arises with connecting series turn capacitances that are standalone capacitors (e.g., discrete capacitors) to turns in inner layers. Using vias to connect to the inner layers may lead to the sacrifice of conductor area in the other layers. The inventors have recognized a way to use space efficiently is to position vias in between the gaps between capacitor pads to which the standalone capacitors are soldered.

FIG. 6A-6D show a 4-layer PCB having four-turn coils in layers 1 and 2. Layer numbering: top=1, top inner=2, bottom inner=3, bottom=4. In particular, FIG. 6A shows a top view of the top layer, FIG. 6B shows a zoomed in portion of FIG. 6A showing the area around and between the capacitor pads 61, FIG. 6C shows a bottom view of the bottom layer, and FIG. 6D shows a zoomed in portion of FIG. 6C showing the area around and between the capacitor pads 61. In this example layers 1 and 2 are 4-turn copper windings and layer 4 is for the return trace. To give layer 2 access to connect to standalone capacitors, the capacitor pads 61 for layer 1 are made to have a large gap between pads. In between these pads are the through vias 62 which are connected to layer 2, and the capacitor pads 61 are placed on the bottom layer (layer 4), wherein the vias 62 are shorted to the capacitor pads. This provides a way to use the through via process, which may be less expensive than blind and nested via processes, to get access to an inner layer. Beneficially, the vias 62 do not cut out conduction area from the top layer (layer 1). In this example, layer 3 may be blank. However, in other embodiments layer 3 may include a coil layer.

### Integrated Series Turn Capacitances

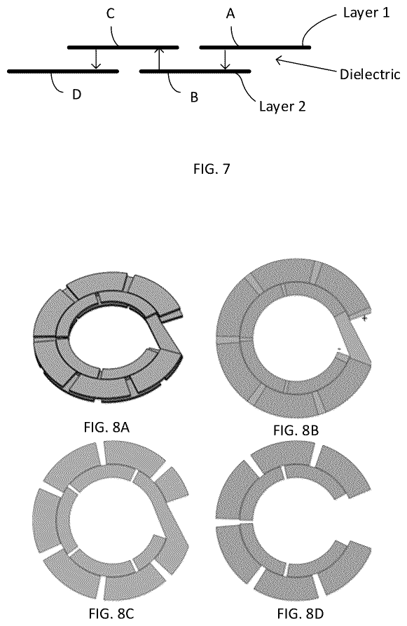

In some embodiments, series turn capacitances may be formed in an integrated manner. In a multilayer structure with thin-layer conductors one or more series turn capacitances may be formed by two layers of thin-layer conductors of the multilayer structure separated by a dielectric. FIG. 7 illustrates a structure including integrated series turn capacitances between two layers. As can be seen, conductor A of Layer 1 partially overlaps (in the vertical direction) with conductor B of Layer 2, forming a capacitance between them. Conductor B partially overlaps with conductor C of Layer 1, forming a capacitance between them. Conductor C partially overlaps with conductor D of Layer 2, forming a capacitance between them. Alternating current (AC) flows through the conductors A-D and their integrated series turn capacitances along the direction of the arrows shown in FIG. 7. That is, alternating current flows back and forth between conductors of Layers 1 and 2 through the integrated capacitances. Capacitance is proportional to the area of overlap between the conductors in different layers, so the capacitance may be selected by varying the overlap area.

FIGS. 8A-8D show a perspective view (FIG. 8A), top view (FIG. 8B), top view of the bottom layer (Layer 2) (FIG. 8C), and top view of the top layer (Layer 1) (FIG. 8D) of one example of a coil with integrated series turn capacitances as illustrated in FIG. 7. The conductors in Layer 1 and Layer 2 extend in a circumferential direction with gaps separating adjacent conductors (e.g., A, C) in the same layer, with conductors in different layers partially overlapping with one another to form series turn capacitances. With this design, a “turn” utilizes conductors in both layers since alternating current flows back and forth between the two layers as it goes around the circumference of the coil. In this example, a coil is shown having two turns that are electrically isolated from one another. However, this is an example, and a coil with integrated series turn capacitances may be formed of any number of one or more turns. Further, although an example is shown with two layers, in other examples a coil with integrated series turn capacitances may be formed in more than two layers. For example, in a three-layer structure a capacitance may be formed between Layer 1 and Layer 2, then between Layer 2 and Layer 3, then between Layer 3 and Layer 2, then between Layer 2 and Layer 1, going around the circumference of the coil. Further, although an example is shown in FIGS. 8A-8D with eight series turn capacitances in the inner turn and twelve series turn capacitances in the outer turn, the apparatus and techniques described herein are not limited in this respect, as the number of series turn capacitances in a turn may be zero or more, and the number of series turn capacitances may be the same or different for different turns. Further, in some embodiments an electromagnetic component may have series turn capacitances of different types. For example, one or more series turn capacitances may be formed by integrated series turn capacitances and one or more series turn capacitances may be formed by standalone capacitors.

### Concentric Turns

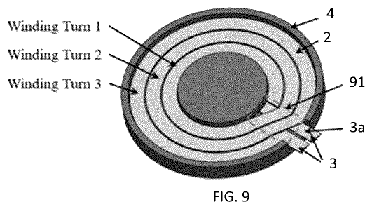

Electromagnetic components with thin-layer windings are often made of winding turns in a spiral configuration as shown in FIG. 1B, in which the radius of the winding continuously varies. The inventors have recognized and appreciated the performance of thin-layer windings can be improved by using concentric turns with a transition region between turns of different radius. The turns may be circular and may have a constant radius outside of the transition region, as shown in FIG. 9 for a 3-turn winding. Within the transition region 91 the trace connecting adjacent turns extends from one radial position corresponding to a first turn to a second radial position corresponding to a second turn. Within the transition region 91 the trace extends in a direction that has a radial component to transition from one radius to another. In some embodiments, the transition region 91, which is the area of the winding (in top view) with traces that transition from one radius to another, is less than one quarter of the total area of the winding (which is the area between the inner radius of the innermost turn to the outer radius of the outermost turn).

There are a number of advantages to such a configuration. It allows more effective use of the available winding space, thereby resulting in lower conduction loss. It also results in the inner edge of the planar winding approximately following the center post of the magnetic core, as shown in FIG. 9, which provides magnetic field lines which are approximately parallel to the plane of the multi-turn winding; this in turn reduces the eddy current induced in the windings, further reducing loss dissipated in the winding. In addition, in spiral windings, the current flow has a small radial component at all circumferential positions whereas in windings with concentric turns, the current flow has a radial component only inside the winding turn transition region. The concentration of radial current flow in a small region also allows for cancellation of the impact of such radial currents resulting in additional performance improvements, as discussed further below.

### Current in the Transition Region

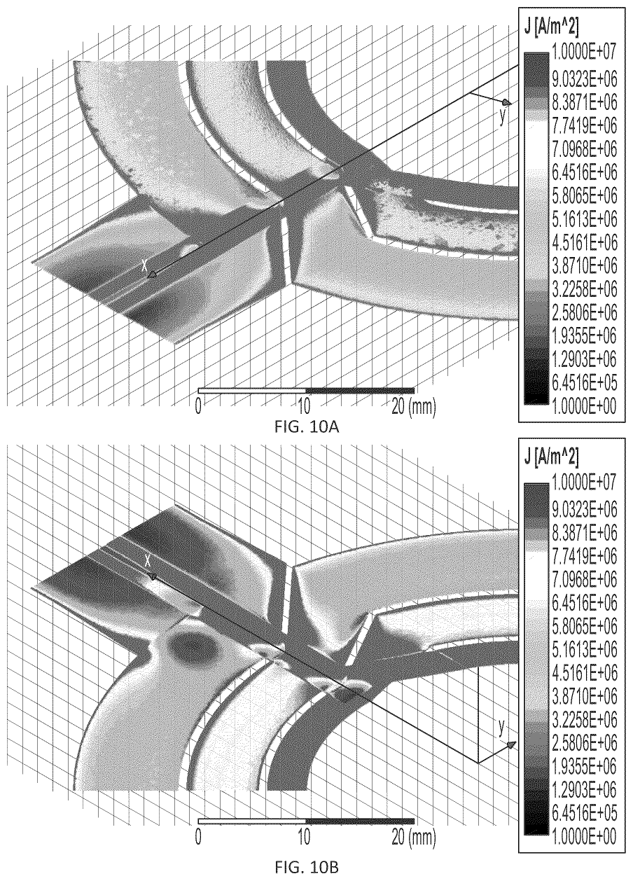

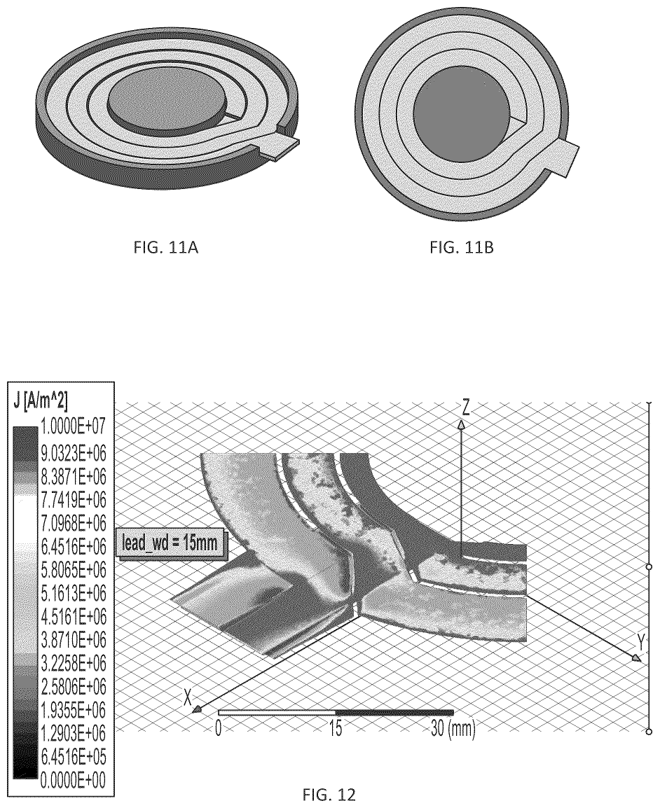

Single-turn coils have a 1-dimensional current flow (circumferential direction). Multi-turn coils may have transition regions from one turn to another, which results in current flow in a second dimension (radial direction). This current flow in the second dimension results in current crowding at the edges of the conductors in the transition region, as shown in the simulation results illustrated in FIGS. 10A and 10B for top and bottom views.

In some embodiments, the magnetic field due to the radial component of the traces in the transition region can be compensated by positioning the return trace above or below the transition region, as shown in FIG. 11A (perspective view) and FIG. 11B (top view). FIG. 12 shows a simulation result illustrating that the current density is reduced with respect to FIGS. 10A and 10B.

Complete covering provides good current distribution, but higher parasitic capacitance. Power loss at the operating frequency can be controlled by adding capacitance for each turn to resonate with the inductance of the corresponding turn. However, the parasitic capacitance may lead to higher harmonic currents, which may impact circuit performance. Partial covering may approach complete covering in performance, with a lower or controllable parasitic capacitance. Parasitic capacitance can be controlled to provide high impedance at higher harmonics to reduce high-harmonic currents.

Two Traces with Opposing Currents

Performance of electromagnetic components may be improved by careful placement of planar conductors relative to one another. In regions where two planar conductors have current flowing in the opposite directions, rather than placing them side by side, as shown in FIG. 13A, better performance may be achieved by stacking the two planar conductors (making the sides with the larger dimension adjacent to one another), as shown in FIG. 13B. As shown in FIG. 13B, stacking planar conductors with opposite currents results in better current distribution compared to placing them side by side. The two conductors may not need to have the same width in the case of stacking the two conductors (FIG. 13B). If one conductor is narrower than the other one, the current in the wider conductor will flow mainly in the region of overlap.

This is useful in designing how to connect the coils to the power electronics circuits. For example, the lead design of FIG. 9 may result in additional losses because the two winding leads, with current flowing in opposite directions, are side by side. So current in the leads will crowd in the inner edges of those two leads.

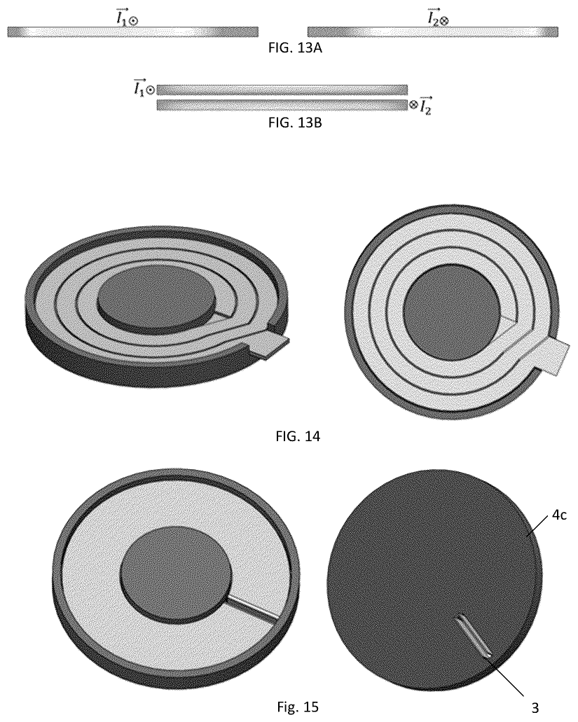

The lead design of FIG. 14 provides lower loss because the two leads 3 are stacked such that they overlap one another (with their widest dimensions facing each other, as opposed to their narrowest dimensions, as in the previous example). This allows the current in the leads to utilize the entire width of the leads.

In other embodiments, the winding leads 3 may extend through an opening in the backplate of the magnetic core, as shown in FIG. 15. Alternatively, each leads extending through opening the backplate may be replaced by one or more rows of pins or wires.

Various aspects of the apparatus and techniques described herein may be used alone, in combination, or in a variety of arrangements not specifically discussed in the embodiments described in the foregoing description and is therefore not limited in its application to the details and arrangement of components set forth in the foregoing description or illustrated in the drawings. For example, aspects described in one embodiment may be combined in any manner with aspects described in other embodiments.

Use of ordinal terms such as “first,” “second,” “third,” etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements.

The terms “substantially,” “approximately,” “about” and the like refer to a parameter being within 10%, optionally less than 5% of its stated value.

Also, the phraseology and terminology used herein is for the purpose of description and should not be regarded as limiting. The use of “including,” “comprising,” or “having,” “containing,” “involving,” and variations thereof herein, is meant to encompass the items listed thereafter and equivalents thereof as well as additional items.

1. An electromagnetic component, comprising:
a thin conductor layer having traces extending along a circumferential direction of the electromagnetic component and having widths extending along a radial direction of the electromagnetic component, wherein the widths are selected such that alternating current distributions in the traces approximate an alternating current distribution in a single trace having a same radial extent as the traces.

2. The electromagnetic component of claim 1, wherein the traces include a first trace having a first width and a second trace having a second width, wherein the first trace is an innermost trace of the thin conductor layer and the second width is greater than the first width.

3. The electromagnetic component of claim 2, wherein the traces include a third trace having a third width greater than the second width, the third trace being farther from a center of the electromagnetic component in a radial direction than the second trace.

4. The electromagnetic component of claim 1, further comprising a magnetic core, wherein the thin conductor layer is disposed within the magnetic core.

5. The electromagnetic component of claim 4, wherein the magnetic core comprises a center post and an outer rim and the thin conductor layer is between the center post and the outer rim.

6. The electromagnetic component of claim 1, wherein the traces are in series with one another.

7. An electromagnetic component, comprising:
a thin conductor layer having traces extending along a circumferential direction of the electromagnetic component and having widths extending along a radial direction of the electromagnetic component, wherein the traces include a first trace having a first width, wherein the first trace is an innermost trace of the thin conductor layer,
wherein the first width is selected such that
$${w}_{1} < 0.97 * \frac{{r}_{w o u t} - {r}_{w i n}}{{N}^{5 / 4}} ,$$
and
wherein w₁ is the first width, r_{win} is an inner radius of the traces, r_{wout} is an outer radius of the traces, and N is a quantity of the traces.

8. The electromagnetic component of claim 7, wherein the traces further include a second trace having a second width larger than the first width, the second trace being radially adjacent the first trace, wherein the second width is selected such that w₂>\sqrt{2}*w₁, wherein w₂ is the second width.

9. The electromagnetic component of claim 8, wherein the traces further include a third trace having a third width larger than the first width, the third trace being radially adjacent the second trace on an outer side of the second trace, wherein the third width is selected such that w₃>\sqrt{3}*w₁, wherein w₃ is the third width.

10. An electromagnetic component, comprising:
a thin conductor layer having N traces extending along a circumferential direction of the electromagnetic component and having widths extending along a radial direction of the electromagnetic component, wherein the traces include a first trace having a first width w₁, wherein the first trace is an innermost trace, and the traces include second and third traces having widths wₖ>\sqrt{k}*w₁, wherein k is an index of the second and third traces equal to 2 or 3, respectively, with the second trace being radially adjacent to the first trace and the third trace being radially adjacent to the second trace on an outer side of the second trace.

11. The electromagnetic component of claim 10, wherein the traces further comprise at least one additional trace outside the third trace having a width wₖ>2*w₁, wherein wₖ is a width of the trace having index k, wherein the index k of a trace is the number of the trace starting with the innermost trace as index 1 and incrementing by one counting radially outward from the innermost trace.

12. The electromagnetic component of claim 10, wherein
$${w}_{1} < 0.97 * \frac{{r}_{w out} - {r}_{w i n}}{{N}^{5 / 4}} ,$$
and wherein r_{win} is an inner radius of the traces and r_{wout} is an outer radius of the traces.

13. A method of designing an electromagnetic component comprising a thin conductor layer having traces extending along a circumferential direction of the electromagnetic component and having widths extending along a radial direction of the electromagnetic component, the method comprising:
obtaining a distribution of alternating current density vs. radial position of the electromagnetic component for a single trace having a same radial extent as the traces;
integrating or summing the distribution over radial position to determine a total alternating current;
dividing the total alternating current by a number N of the traces to determine an alternating current per trace; and
selecting the widths of each of the N traces, which, based on the distribution, results in the N traces having the determined alternating current per trace.

14. The method of claim 13, wherein the determining of the widths comprises selecting a width of a first trace by integrating or summing along the distribution along a radial direction until a width is reached in which an alternating current for the first trace is equal to the determined alternating current per trace.

15. The method of claim 14, wherein the first trace is an innermost or outermost trace.

16.-37. (canceled)
